(19) United States
(12) Patent Application Publication
(10) Pub. No.: US 2007/0246722 A1
(43) Pub. Date: Oct. 25, 2007

(54) Sealed LED having improved optical transmissibility

(76) Inventor: Keat Chuan Ng, Penang (MY)

Correspondence Address: Kathy Manke;Avago Technologies Limited, 4380 Ziegler Road, Fort Collins, CO, 80525, US

(21) Appl. No.: 11/410,353

(22) Filed: Apr. 25, 2006

(51) Int. Cl. H01L 33/00; H01L 21/00

(52) U.S. Cl. 257/98; 438/22

(57) ABSTRACT

A light emitting diode (LED) having enhanced integrity. The light emitting source of the LED is preferably an LED chip encapsulated by a compliant material, preferably silicone. The LED chip is supported within an optical shell so that a gap exists between the compliant material and the interior surface of the shell, thereby avoiding delamination.

### RELATED APPLICATIONS

This application is related to concurrently filed and commonly assigned U.S. patent application Ser. No. [Attorney Docket No. 70051681-01] entitled “AN IMPROVED LIGHT-EMITTING DIODE”, the disclosure of which is hereby incorporated herein by reference.

### TECHNICAL FIELD

The present invention relates to light emitting diode (LED) and the method of manufacturing same. More particularly, the present invention relates to a sealed LED having improved optical transmissibility and the method of manufacturing same.

### BACKGROUND OF THE INVENTION

Light emitting diodes (LED) are frequently encapsulated within an optical or protective shell. To improve both reliability and the integrity of the unit, a silicone gel is injected within the shell during the manufacturing process. The gel completely encapsulates the LED chip and bond wire.

During the manufacturing process, silicone gel is placed within the optical shell after the LED chip is inserted. Once the silicone has cured, the LED chip and bond wire are integrally sealed within the optical shell. Over time, however, it has been determined that the silicone separates at various locations from the interior surface of the shell. This separation affects the optical integrity of the unit, since light emitting from the LED chip may be inhibited due to the separation at various location at the inner surface of the optical shell. The end result is inconsistent illumination or no illumination from all or part of an LED. In an effort to overcome this problem, some use has been made of a hard silicone to shape and form the shell. However, this grade of silicone is expensive and not cost effective due to the quantity needed. Also, over time, this type of silicone has a tendency to become brittle and crack, resulting once again in an impediment to optical transmissibility.

### BRIEF SUMMARY OF THE INVENTION

An improved light device which includes an outer shell forming an interior cavity. The shell is translucent to light emanating from within the cavity. A light source is mounted within the cavity and is surrounded by a compliant and translucent material. The light source is positioned within the interior of the shell so that a gap exists between the compliant material and the interior surface of the shell.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and specific embodiment disclosed may be readily utilized as the basis for modifying or designing other structures for carrying out the same purposes of the present invention. It should also be realized by those skilled in the art that such equivalent constructions do not depart from the spirit and scope of the invention as set forth in the appended claims. The novel features which are believed to be characteristic of the invention, both as to its organization and method of operation, together with further objects and advantages will be better understood from the following description when considered in connection with the accompanying figures. It is to be expressly understood, however, that each of the figures is provided for the purpose of illustration and description only and is not intended as a definition of the limits of the present invention.

### BRIEF DESCRIPTION OF THE DRAWINGS

For a more complete understanding of the present invention, reference is now made to the following descriptions taken in conjunction with the accompanying drawing, in which:

FIG. 1 is an elevation view of an arrangement of a LED assembly, according to embodiments of the present invention.

FIG. 2 is an elevation view of an arrangement of a LED assembly, according to embodiments of the present invention.

### DETAILED DESCRIPTION OF THE INVENTION

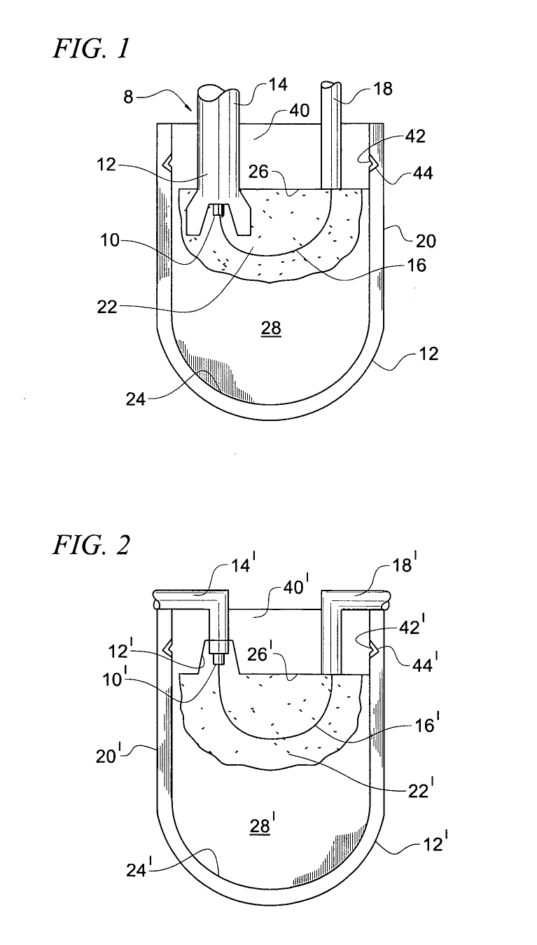

Referring now to FIG. 1, base 40 supports a conventional LED assembly 8. Typically, LED assembly 8 comprises two electrical connections 14 and 18 which, in this case, penetrate base 40. Electrical connection 14 includes a receptacle 12 on which is mounted a light emitting source, such as LED chip 10. A bond wire 16 connects chip 10 and electrical connection 18. Base 40 is positioned within optical shell 20 and secured in place by any number of conventional techniques. For example, base 40 may include a ridge 42 which is adapted to seat within a recess 44 of optical shell 20. In this manner, once inserted the position of base 40 is predetermined with respect to shell 20. During the manufacturing process, a compliant and translucent material, such as silicone gel 22, is placed on top of base 40. An adequate amount of silicone 22 is used to fully saturate at least chip 10. Additionally, enough silicone 22 is used to allow it to contact surface 26 of base 40. Therefore, following curing chip 10 is preferably fully encapsulated to surface 26 of base 40. Silicones are also known as synthetic polymers. Frequently, it is more properly designated as a synthetic polymer containing an Si—O—Si backbone, with each silicon atom bearing two methyl groups. This general description defines the broad class of polymers known as silicones. Note that other compliant and translucent materials may be used, so long as the light emitting source is encapsulated.

Once silicone 22 cures, base 40 is inserted within optical shell 20 and secured in position by ridge 42. In this manner, an air gap 28 is provided between silicone 22 and inner surface 24 of shell 20. The presence of such an air gap provides a consistent optical affect through the shell and prevents the detrimental effects resulting from delamination over time.

Referring now to FIG. 2, the present invention is depicted employing surface mounted technology (SMT), well known to those skilled-in-the-art. LED chip 10′ is mounted on base 40′ within optical shell 20′. Chip 10′ is disposed on and electrically connected to connection 14′ and to electrical connection 18′ through bond wire 16′. A sufficient amount of silicone 22′ is present to fully encapsulate chip 10′ and wire 16′ and secure it to the surface 26′ of base 40′. In this manner, the integrity of the light emitting portion of the LED, wire 16′, is secured. Additionally, an air gap 28′ is thereby provided between silicone 22′ and optical shell 20′.

Referring to FIGS. 1 and 2, the surface 26/26′ may include etchings or other minor irregularities to improve the cured adhesive contact between silicone 22/22′ and base 40/40′. Such enhanced sealing further promotes the integrity and reliability of the LED assembly.

In the manufacture of the present invention, the compliant and translucent material, such as silicone 22/22′, may be installed using a conventional pre-dip method. In this application, silicone gel 22/22′ is placed on surface 26/26′ in a liquid state. Preferably, an adequate amount of silicone is placed to encapsulate chip 10/10′.

Following the curing of the silicone, LED assembly 8 is inserted within optical shell 20/20′. Base 40/40′ is inserted sufficiently to permit ridge 42/42′ to engage recess 44/44′ of optical shell 20/20′ thereby orienting the base, and therefore the LED assembly, within a predetermined position within the interior of optical shell 20. This further serves to ensure the existence of air gap 28/28′ within optical shell 20/20′ eliminating delamination and the detrimental effects resulting therefrom.

Although the present invention and its advantages have been described in detail, it should be understood that various changes, substitutions and alterations can be made herein without departing from the spirit and scope of the invention as defined by the appended claims. Moreover, the scope of the present invention is not intended to be limited to the particular embodiments of the process, machine, manufacture, composition of matter, means, methods and steps described in this specification. As one of ordinary skill in the art will readily appreciate from the disclosure of the present invention, processes, machines, manufacture, compositions of matter, means, methods, or steps, presently existing or later to be developed that perform substantially the same function or achieve substantially the same result as the corresponding embodiment described herein may be utilized according to the present invention. Accordingly, the appended claims are intended to include within their scope such processes, machines, manufacture, compositions of matter, means, methods or steps.

What is claimed is:

1. A light device comprising:
a shell forming a cavity, said shell being translucent to light emanating from within said cavity;
a light source mounted within said cavity; and
compliant material surrounding said light source and positioned such that light from said light source passes through said compliant material and though a gap between said compliant material and said shell.

2. The device of claim 1 wherein said gap is an air gap.

3. The light device of claim 1, further comprising:
a base that supports the light source; and
means for engaging said base to said shell.

4. The device of claim 1 wherein said source comprises an light emitting diode (LED) chip.

5. The device of claim 1 wherein said source comprises a surface mounted light emitting diode (LED) chip.

6. The device of claim 1 wherein said compliant material comprises silicone.

7. The device of claim 3 wherein said base includes an etched surface on which said source is mounted so as to improve the integrity of the contact between said compliant material and said base.

8. The device of claim 3 wherein said engaging means comprises a protruding ridge extending from the peripheral edge of the base; and said shell includes a recessed portion capable of receiving said ridge to secure the base within said shell in a predetermined orientation.

9. A light emitting diode (LED) comprising:
an optical shell;
a base having an etched surface;
means for engaging said base to said optical shell in a predetermined orientation;
an LED chip mounted on said etched surface and oriented within said optical shell; and
a coating of compliant material over said chip and at least a portion of said etched surface so that a gap exists within the interior of the optical shell between said compliant material and said shell.

10. The LED of claim 9 wherein said compliant material comprises silicone.

11. A method for manufacturing a light emitting diode (LED) with improved optical transmissibility through an optical shell, comprising the steps of:
providing a base having an LED chip mounted thereon;
coating the LED chip with silicone;
inserting the LED chip within the optical shell; and
engaging the base to the shell thereby forming an air gap between the interior of the optical shell and the silicone coating.

12. The method of claim 11, further comprising:
allowing the silicone to cure prior to its placement within the optical shell.

13. The method of claim 11 further comprising the step of etching the surface of the base supporting the LED chip to improve the integrity of the seal between the silicone and the base during curing.

14. The method of claim 11 further comprising:
allowing the silicone to cure prior to inserting.
